(19) United States
(12) Patent Application Publication
(10) Pub. No.: US 2008/0186673 A1
(43) Pub. Date: Aug. 7, 2008

(54) Refrigerant based heat sink for video game console

(76) Inventor: Kent T.J. Hsu, Taipei City (TW)

Correspondence Address: TROXELL LAW OFFICE PLLC, SUITE 1404, 5205 LEESBURG PIKE, FALLS CHURCH, VA, 22041, US

(21) Appl. No.: 11/700,961

(22) Filed: Feb. 1, 2007

(51) Int. Cl. H05K 7/20; H05K 5/00

(52) U.S. Cl. 361/689

(57) ABSTRACT

A device for cooling a video game console having inlet apertures is disclosed. The device includes a housing including a rear recess, a front air inlet, and a cooling air outlet; a heat sink mounted in the recess and including a refrigeration coil with refrigerant contained therein, and a front channel; and a fan mounted in the channel and aligned with the air inlet. The video game console is mounted rearward of the heat sink with the apertures engaged with the cooling air outlet such that activating the device and the video game console will draw hot air from within the video game console through a surface of the refrigeration coil to be cooled by the circulating refrigerant prior to supplying cool air from the channel into the video game console through the cooling air outlet and the apertures. The video game console can be “PS_3”, “Wii”, “X_Box”.

### BACKGROUND OF THE INVENTION

1. Field of Invention

The invention relates to cooling devices and more particularly to a cooler having a refrigerant based heat sink mounted in a video game console (e.g., “PS_{—}3”, “Wii”, or “X_Box”).

2. Description of Related Art

Electronic devices (e.g., video game consoles) have many components that produce large amounts of heat during operation, including but not limited to CPU and chipset. This heat must be dissipated in order to keep these components within their safe operating temperatures. This is typically done by using heat sinks for increasing the surface area which dissipates heat, or fans for speeding up the exchange of air heated by the components and cooling ambient air. Thus, it is desirable to provide a novel cooling device for effectively dissipating heat generated by the components of a video game console during operation.

### SUMMARY OF THE INVENTION

It is therefore one object of the invention to provide a device for cooling a video game console having a plurality of apertures, comprising a housing including a rear recess, a front air inlet, and a cooling air outlet at one side of the recess; a heat sink mounted in the recess and including a refrigeration coil with refrigerant contained therein, and a front channel; and a fan mounted in the channel and aligned with the air inlet, wherein the video game console is mounted in a rear of the heat sink with the apertures engaged with the cooling air outlet such that activating the device and the video game console will draw hot air from within the video game console through a surface of the refrigeration coil to be cooled by the refrigerant circulating through the refrigeration coil prior to supplying cool air from the channel into the video game console through the cooling air outlet and the apertures.

In one aspect of the invention the video game console is “PS_{—}3”.

In another aspect of the invention the video game console is “Wii”.

In a further aspect of the invention the video game console is “X_Box”. The above and other objects, features and advantages of the invention will become apparent from the following detailed description taken with the accompanying drawings.

### BRIEF DESCRIPTION OF THE DRAWINGS

FIG. 1 is a perspective view of a cooler incorporating a preferred embodiment of refrigerant based heat sink according to the invention;

FIG. 2 is an exploded perspective view of FIG. 1;

FIG. 3 is a perspective view of the cooler to be assembled with a video game console “PS_{—}3”;

FIG. 4 is a perspective view of the assembled cooler and the video game console “PS_{—}3”;

FIG. 5 is another perspective view of FIG. 4;

FIG. 6 schematically depicts hot and cold air flows in the cooler and the video game console “PS_{—}3” during operation;

FIG. 7 is a perspective view of the cooler assembled with a video game console “Wii”; and

FIG. 8 is a perspective view of the cooler assembled with a video game console “X_Box”.

### DETAILED DESCRIPTION OF THE INVENTION

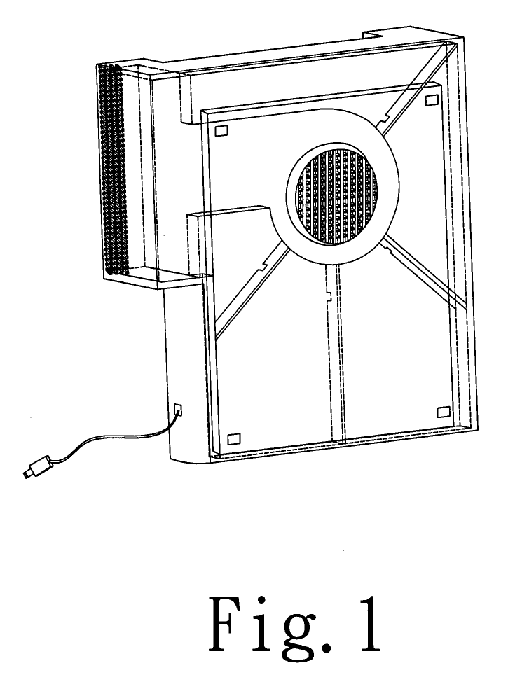

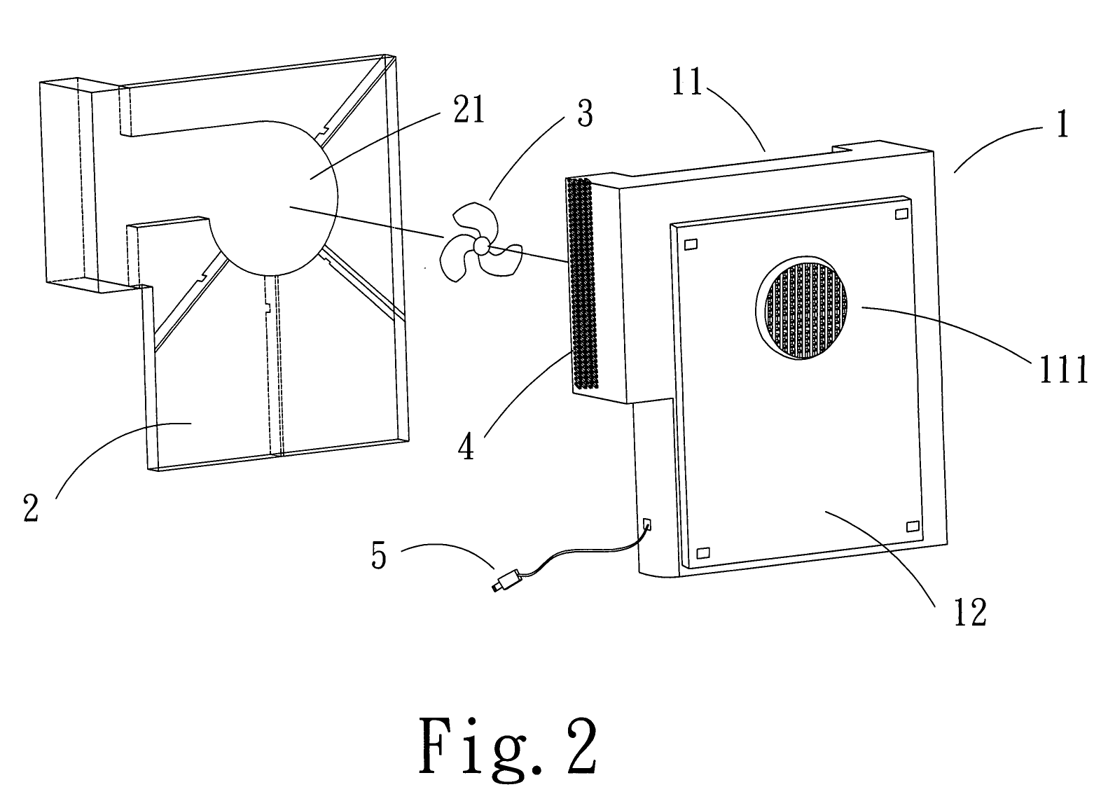

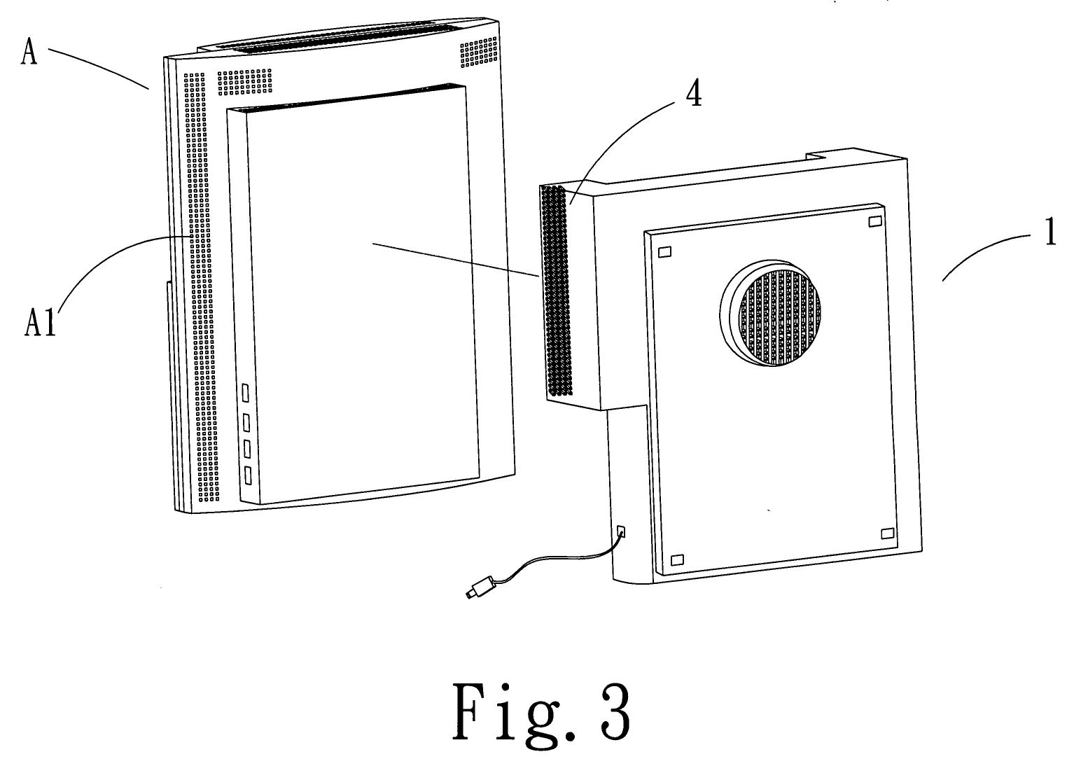

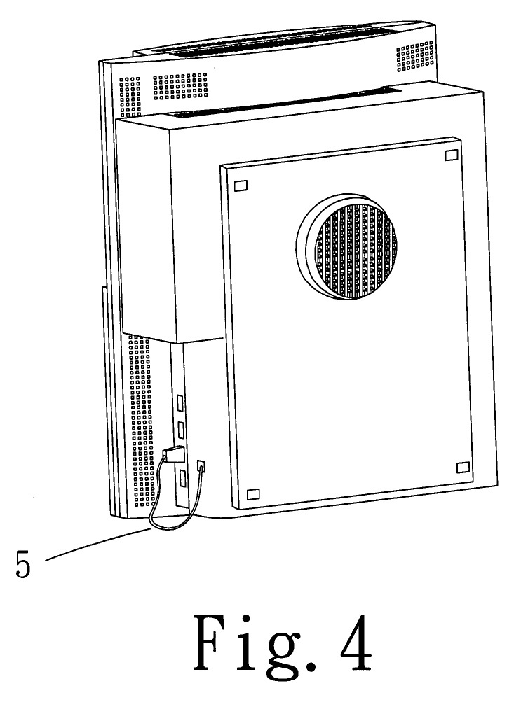

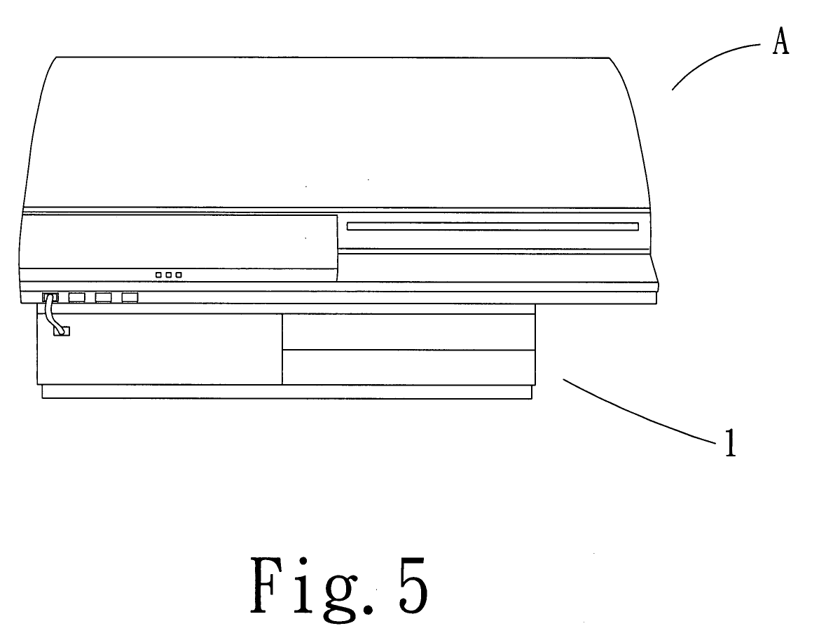

Referring to FIGS. 1 to 5, a preferred embodiment of the invention is shown and comprises the following components.

A cooler 1 comprises a rear recess 11, a front panel 12 having an air inlet 111, a cooling air outlet 4 at one side of the recess 11, and a USB power cord 5.

A plate shaped heat sink 2 comprises a closed refrigeration coil (not shown) with refrigerant contained therein wherein the refrigerant is circulated during cooling operation, and a front channel 21. A fan 3 is mounted in the channel 21. The heat sink 2 is again mounted in the recess 11 wherein the fan 3 is aligned with the air inlet 111 so as to facilitating the introduction of air from the air inlet 111.

A video game console A is adapted to mount in the rear of the assembled cooler 1 and the heat sink 2. The video game console A has a plurality of apertures A1 arranged in rows and columns. The cooling air outlet 4 is closely engaged with the apertures A1.

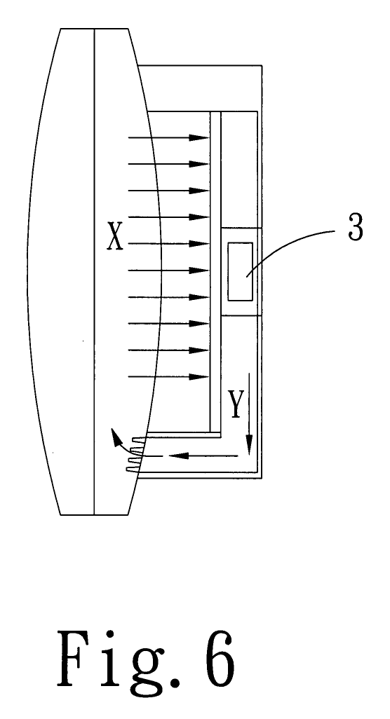

Referring to FIG. 6 in conjunction with FIGS. 1 to 5, a cooling operation of the invention will be described in detailed below. First, connect the power cord 5 to a power source (not shown). Next, turn on an on/off switch (not shown) to activate the cooler 1, the heat sink 2, and the video game console A. As such, hot air (indicated by arrows designated as X) in the video game console A is drawn through the surface of the refrigeration coil of the heat sink 2 to be cooled by the refrigerant circulating through the refrigeration coil. As such, air in the channel 21 is cooled. Next, cool air (indicated by arrow designated as Y) is continuously supplied from the channel 21 to components inside the video game console A through the cooling air outlet 4 and the apertures A1 as the fan 3 rotates. As a result, temperature inside the video game console A is reduced significantly so as to keep the heat at a safe level.

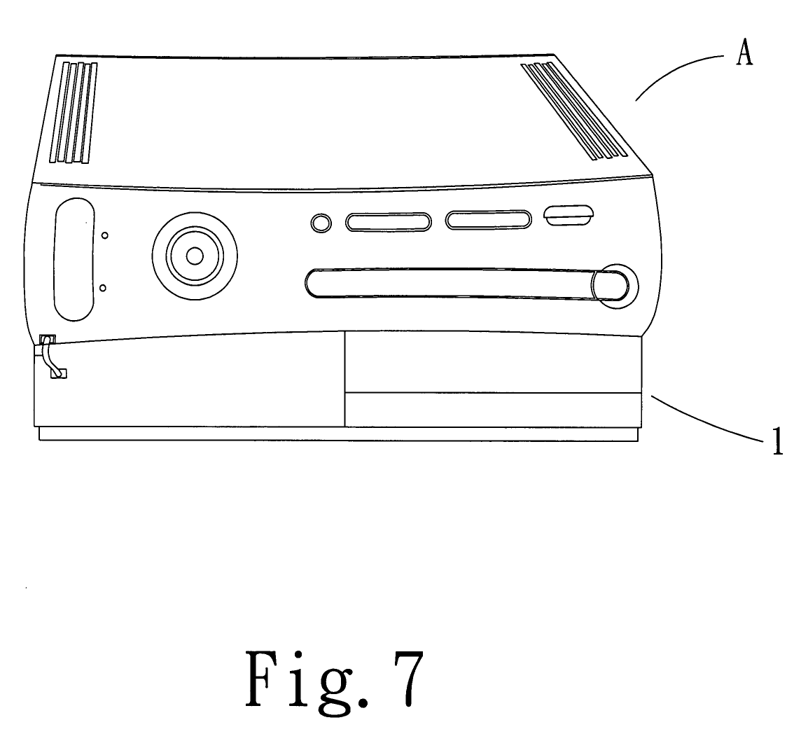

Referring to FIG. 7, the cooler 1 is assembled with a video game console “Wii” A in another configuration of the invention.

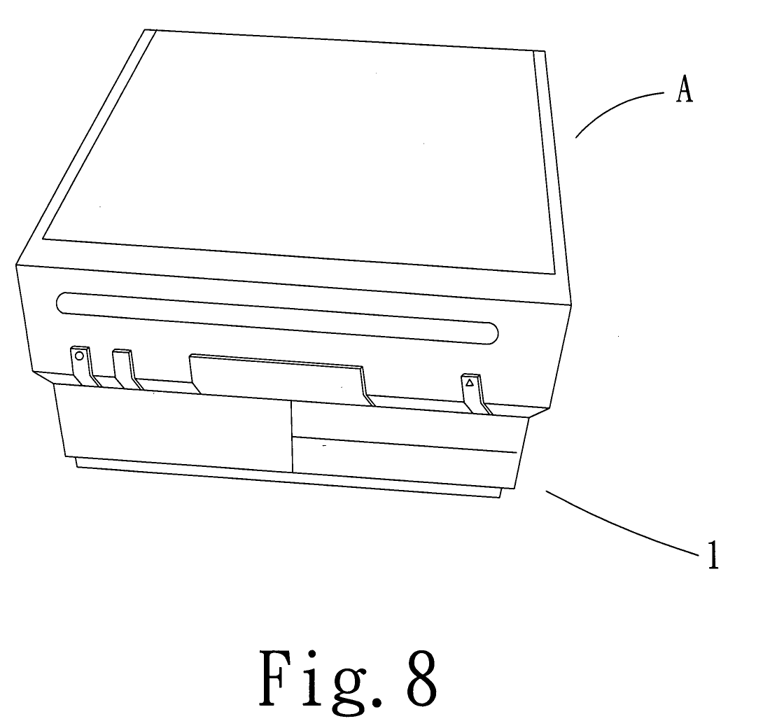

Referring to FIG. 8, the cooler 1 is assembled with a video game console “X_Box” A in still another configuration of the invention.

While the invention herein disclosed has been described by means of specific embodiments, numerous modifications and variations could be made thereto by those skilled in the art without departing from the scope and spirit of the invention set forth in the claims.

What is claimed is:

1. A device for cooling a video game console having a plurality of apertures, comprising:
a housing including a rear recess, a front air inlet, and a cooling air outlet at one side of the recess;
a heat sink mounted in the recess and including a refrigeration coil with refrigerant contained therein, and a front channel; and
a fan mounted in the channel and aligned with the air inlet,
wherein the video game console is mounted in a rear of the heat sink with the apertures engaged with the cooling air outlet such that activating the device and the video game console will draw hot air from within the video game console through a surface of the refrigeration coil to be cooled by the refrigerant circulating through the refrigeration coil prior to supplying cool air from the channel into the video game console through the cooling air outlet and the apertures.
